(19) United States
(12) Patent Application Publication
(10) Pub. No.: US 2009/0087546 A1
(43) Pub. Date: Apr. 2, 2009

(54) PROCESS FOR PRODUCING ELECTROLUMINESCENT DEVICE

(75) Inventors: Yasuhiro Ilzumi, Setagaya-Ku (JP); Masaya Shimogawara, Tsukuba-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: DAI NIPPON PRINTING CO., LTD., Shinjuku-Ku (JP)

(21) Appl. No.: 12/236,000

(22) Filed: Sep. 23, 2008

(30) Foreign Application Priority Data
Sep. 28, 2007 (JP) 2007-256855

(51) Int. Cl. B05D 5/12

(52) U.S. Cl. 427/66

(57) ABSTRACT

A process for producing an electroluminescent device comprises the steps of preparing a substrate 1, forming a first electrode layer 2 on the substrate 1, and forming a luminescent layer 3 on the first electrode layer 2 by applying a luminescent-layer-forming coating liquid containing quantum dots 22, each quantum dot 22 being surrounded by organic ligands 21. After the luminescent-layer-forming step, the step of removing the organic ligands 21 from the quantum dots 22 by subjecting the luminescent layer 3 to UV-ozone cleaning is performed. After the organic-ligand-removing step, the step of forming a second electrode layer 4 on the luminescent layer 3 in which the organic ligands 21 have been removed from the quantum dots 22 is performed.

### CROSS-REFERENCE TO RELATED APPLICATION

This is a patent application claiming a priority on the basis of Japanese Patent Application No. 2007-256855 filed on Sep. 28, 2007. The whole descriptions of the Japanese Patent Application No. 2007-256855 are incorporated herein by reference.

### BACKGROUND OF THE INVENTION

1. Field of the Invention

The present invention relates to a process for producing an electroluminescent (hereinafter sometimes abbreviated to “EL”) device comprising a luminescent layer containing quantum dots.

2. Background Art

An EL device is that holes and electrons injected from two facing electrodes combine with each other in a luminescent layer to generate energy to excite a luminescent material in the luminescent layer, whereby the luminescent layer emits light whose color depends on the luminescent material. EL devices are attracting much attention as self-luminous panel display elements.

In recent years, light-emitting devices comprising luminescent layers containing semiconductor quantum dots have been proposed and developed. Quantum dots are crystals in a size of several nanometers to several tens nanometers, consisting of a plurality of semiconductor atoms. Such nanometer-sized small crystals do not have a continuous energy band structure but have discrete energy levels. Namely, since quantum dots remarkably show the quantum size effect, their electron containment effect is greater than that of bulk crystals, which are larger than quantum dots in size. Quantum dots, therefore, can cause excitons to recombine with each other with a higher probability.

Further, in a light-emitting device using quantum dots, the emission frequency can be regulated without changing the structure of the light-emitting device. Because of the quantum containment effect, a quantum dot exhibits optical properties that are dependent on its size. For example, it is possible to change the luminescent color of CdSe quantum dot from blue to red by merely changing the size of the quantum dot. Furthermore, a quantum dot emits light in a wavelength range with a relatively narrow half width, and can attain a narrow half width of less than 30 nm, for example. It can therefore be said that quantum dots are excellent as materials for luminescent layers.

Quantum dots are also called nanocrystals, fine particles, colloids or clusters, and those ones that have the quantum size effect are herein referred to as quantum dots.

A known process for forming a luminescent layer by the use of such quantum dots is a spin or dip coating process using a colloidal solution containing quantum dots having organic ligands, such as tri-n-octylphosphine oxide (TOPO), attached to their surfaces (see Published Japanese Translations No. 2005-522005 and No. 2006-520077 of PCT patent applications, for example). The organic ligands attached to the surface of each quantum dot make the dispersibility of the quantum dots excellent.

However, most organic ligands attached to quantum dots do not contribute to luminescence. Moreover, in the above-described luminescent layer using quantum dots having organic ligands attached to their surfaces, the quantum dots are poor in stability in the luminescent layer, so that they are likely to affect life characteristics. Especially when the quantum dots are phosphorescent, life characteristics are apt to be affected by the quantum dots because phosphorescent materials are longer in life than fluorescent ones. Therefore, in order to obtain an EL device having high efficiency and a long life, it is preferable to remove the organic ligands from the quantum dots in the luminescent layer.

Further, in the above luminescent layer formed using quantum dots, since organic ligands are attached to the surfaces of the quantum dots, the distance between two adjacent quantum dots is assumed to be about two times the length of the organic ligand. The luminescent layer therefore can have decreased electrical conductivity. A luminescent layer poor in conductivity adversely affects emission characteristics.

In the aforesaid Published Japanese Translations No. 2006-520077 is proposed a method for removing pyridine attached as the organic ligand to the surfaces of quantum dots contained in an optical layer. This method is that the pyridine is evaporated by compressing (sintering) the optical layer either at a temperature of 300° C., or at a temperature of 150° C. and a pressure of about 1000 bar. However, this publication discloses only the method for removing pyridine used as the organic ligand and describes in detail no methods for removing other types of organic ligands.

### SUMMARY OF THE INVENTION

The present invention was accomplished in the light of the above circumstances. A main object of the present invention is to provide a process for producing an EL device that comprises a luminescent layer containing quantum dots and that is excellent in emission characteristics and life characteristics, the process being applicable to removal of various types of organic ligands attached to the quantum dots.

The first embodiment of the present invention for fulfilling the above object is a process for producing an electroluminescent device, comprising the step of:

preparing a substrate,

forming a first electrode layer on the substrate,

forming a luminescent layer on the first electrode layer by applying, to the first electrode layer, a luminescent-layer-forming coating liquid containing quantum dots, each quantum dot being surrounded by organic ligands,

removing the organic ligands from the quantum dots by subjecting the luminescent layer to UV-ozone cleaning, and

forming a second electrode layer on the luminescent layer in which the organic ligands have been removed from the quantum dots.

According to the process comprising the above steps, UV-ozone cleaning is conducted to remove the organic ligands from the luminescent layer, so that removal of organic ligands of various types can be achieved. It is thus possible to obtain an EL device having high efficiency and a long life.

The process according to the first embodiment of the invention may further comprise, between the first-electrode-layer-forming step and the luminescent-layer-forming step, the step of forming, on the first electrode layer, a hole injection transporting layer of an inorganic material having the property of injecting holes. The reason why an inorganic material is used to form the hole injection transporting layer is that a layer of an inorganic material has stability to the UV-ozone cleaning.

In the first embodiment of the present invention, it is preferred that the quantum dot be composed of a core part made of a semiconductor fine particle and a shell part covering the core part, made from a material having a greater band gap than the semiconductor fine particle. This is because such a structure makes a quantum dot stable.

The second embodiment of the present invention is a process for producing an electroluminescent device, comprising the steps of:

preparing a substrate,

forming a first electrode layer on the substrate,

forming a luminescent layer on the first electrode layer by applying, to the first electrode layer, a luminescent-layer-forming coating liquid containing quantum dots, each quantum dot being surrounded by organic ligands,

removing the organic ligands from the quantum dots by plasma irradiation of the luminescent layer, and

forming a second electrode layer on the luminescent layer in which the organic ligands have been removed from the quantum dots.

According to the process comprising the above steps, plasma irradiation is conducted to remove the organic ligands from the luminescent layer, so that removal of organic ligands of various types can be achieved. It is thus possible to obtain an EL device having high efficiency and a long life.

The process according to the second embodiment of the invention may further comprise, between the first-electrode-layer-forming step and the luminescent-layer-forming step, the step of forming, on the first electrode layer, a hole injection transporting layer of an inorganic material having the property of injecting holes. The reason why an inorganic material is used to form a hole injection transporting layer is that a layer of an inorganic material has stability to plasma irradiation.

In the second embodiment of the present invention, it is preferred that the quantum dot be composed of a core part made of a semiconductor fine particle and a shell part covering the core part, made from a material having a greater band gap than the semiconductor fine particle. This is because such a structure makes a quantum dot stable.

The third embodiment of the present invention is a process for producing an electroluminescent device, comprising the steps of:

preparing a substrate,

forming a first electrode layer on the substrate,

forming a luminescent layer on the first electrode layer by applying, to the first electrode layer, a luminescent-layer-forming coating liquid containing quantum dots, each quantum dot being surrounded by organic ligands,

placing, above the luminescent layer, a photocatalytic treatment layer containing at least a photocatalyst,

removing the organic ligands from the quantum dots by applying energy to the photocatalytic treatment layer, and

forming a second electrode layer on the luminescent layer in which the organic ligands have been removed from the quantum dots.

According to the process comprising the above steps, the treatment using the photocatalytic treatment layer is carried out to remove the organic ligands from the luminescent layer, so that removal of organic ligands of various types can be achieved. It is thus possible to obtain an EL device having high efficiency and a long life.

The process according to the third embodiment of the invention may further comprise, between the first-electrode-layer-forming step and the luminescent-layer-forming step, the step of forming, on the first electrode layer, a hole injection transporting layer of an inorganic material having the property of injecting holes. The reason why an inorganic material is used to form a hole injection transporting layer is that a layer of an inorganic material has stability to the application of energy.

In the third embodiment of the present invention, it is preferred that the quantum dot be composed of a core part made of a semiconductor fine particle and a shell part covering the core part, made from a material having a greater band gap than the semiconductor fine particle. This is because such a structure makes a quantum dot stable.

According to the present invention, since UV-ozone cleaning, plasma irradiation, or treatment using a photocatalytic treatment layer is employed to remove organic ligands from a luminescent layer, the invention is applicable to removal of organic ligands of various types, and, moreover, can provide an electroluminescent device having high efficiency and a long life.

### BRIEF DESCRIPTION OF THE DRAWINGS

FIG. 1 is a flow chart showing a process for producing an EL device according to the first embodiment of the present invention.

FIG. 2 is a schematic view showing a quantum dot surrounded by organic ligands, to be used in the first embodiment of the present invention.

FIG. 2A is a schematic view showing an example of the internal structure of a quantum dot in the first embodiment of the present invention.

FIG. 3 is a flow chart showing another process for producing an EL device according to the first embodiment of the present invention.

FIG. 4 is a flow chart showing a process for producing an EL device according to the second embodiment of the present invention.

FIG. 5 is a flow chart showing another process for producing an EL device according to the second embodiment of the present invention.

FIG. 6 is a flow chart showing a process for producing an EL device according to the third embodiment of the present invention.

FIG. 7 is a flow chart showing another process for producing an EL device according to the third embodiment of the present invention.

### DETAILED DESCRIPTION OF THE INVENTION

A process of the present invention, for producing an EL device, will be hereinafter described in detail. The process of the invention is embodied in three forms that are different in the manner in which organic ligands are removed from quantum dots. The three embodiments will be described below.

### I. First Embodiment

A process for producing an EL device according to this embodiment will be described with reference to the accompanying drawings.

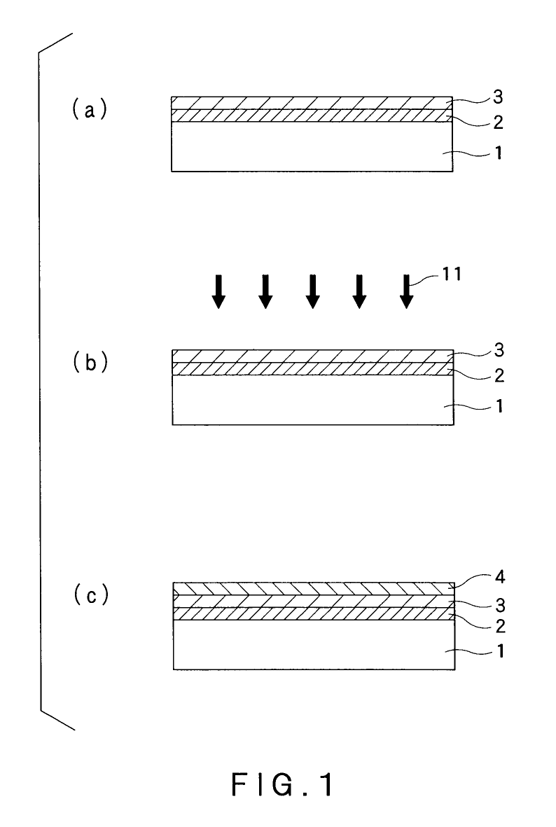

The first embodiment of the process of the invention, for producing an EL device, is characterized by comprising the step of preparing a substrate 1, the step of forming a first electrode layer 2 on the substrate 1, the step of forming a luminescent layer 3 on the first electrode layer 2 by applying, to the first electrode layer 2, a luminescent-layer-forming coating liquid containing quantum dots 22, each quantum dot 22 being surrounded by organic ligands 21, the step of removing the organic ligands 21 from the quantum dots 22 by subjecting the luminescent layer 3 to UV-ozone cleaning, and the step of forming a second electrode layer 4 on the luminescent layer 3 in which the organic ligands 21 have been removed from the quantum dots 22 (see FIGS. 1(a)-1(c)).

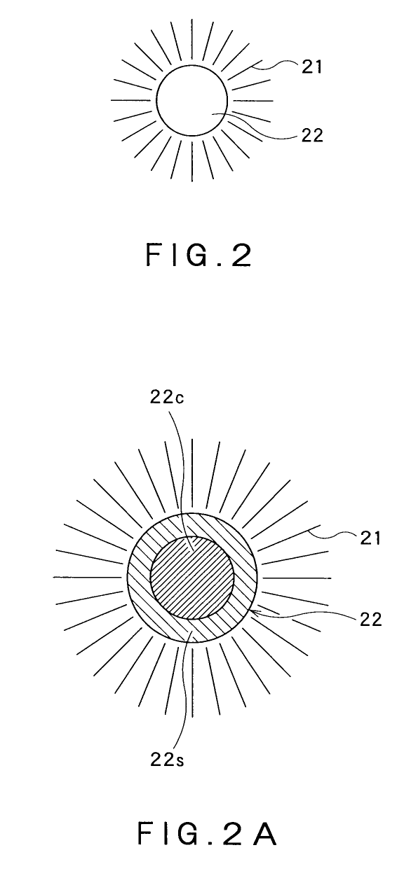

In the present invention, the expression “to remove the organic ligands 21” means not only removing the organic ligands 21 leaving residues, but also removing the organic ligands 21 without leaving residues (see FIG. 2).

FIG. 1 is a flow chart showing a process for producing an EL device according to this embodiment. A substrate 1 is first prepared (substrate-preparing step). Next, a first electrode layer 2 is formed on the substrate 1 (first-electrode-layer-forming step). Subsequently, a luminescent-layer-forming coating liquid containing quantum dots 22, each quantum dot 22 being surrounded by organic ligands 21 (see FIG. 2), is applied to the first electrode layer 2 to form a luminescent layer 3 (FIG. 1(a), luminescent-layer-forming step).

Quantum dots 22, each quantum dot 22 being surrounded by organic ligands 21, as illustrated in FIG. 2, are used in the luminescent-layer-forming coating liquid. Namely, organic ligands 21 are attached to the surfaces of the quantum dots 22, and such quantum dots 22 having organic ligands 21 attached to their surfaces are used in the luminescent-layer-forming coating liquid.

Next, ultraviolet light 11 containing light of 185 nm and that of 254 nm is applied to the luminescent layer 3 (FIG. 1(b), organic-ligand-removing step). The ultraviolet light of 185 nm causes oxygen (O₂) in the air to generate ozone (O₃), and the ultraviolet light of 254 nm acts to decompose the ozone (O₃) into oxygen (O₂) and active oxygen (O), thereby making the area around the luminescent layer 3 rich in active oxygen. When the luminescent layer 3 comes into contact with the active oxygen, the organic ligands 21 existing in the luminescent layer 3 react with the active oxygen to produce an evaporating substance and are thus removed. This is called the UV-ozone cleaning.

Subsequently, a second electrode layer 4 is formed on the luminescent layer 3 in which the organic ligands 21 have been removed from the quantum dots 22 (FIG. 1(c), second-electrode-layer-forming step).

The UV-ozone cleaning can easily achieve removal of a variety of organic materials. According to this embodiment, various types of organic ligands 21 existing in the luminescent layer 3 can be removed by the UV-ozone cleaning. It is thus possible to obtain an EL device having high efficiency and a long life. Further, when an electron transporting layer or the like is formed on the luminescent layer 3 by a coating process after performing the organic-ligand-removing step, there can be obtained increased adhesion between the luminescent layer 3 and the electron transporting layer or the like.

The steps in the process for producing an EL device according to this embodiment will be described hereinafter.

### 1. Luminescent-Layer-Forming Step

The luminescent-layer-forming step in this embodiment is the step of forming the luminescent layer 3 by applying a luminescent-layer-forming coating liquid containing quantum dots 22, each quantum dot 22 being surrounded by organic ligands 21, to the substrate 1 on which the first electrode layer 2 has been formed.

The luminescent-layer-forming coating liquid, the method for forming the luminescent layer 3, the substrate 1, and the first electrode layer 2 will be described below.

### (1) Luminescent-Layer-Forming Coating Liquid

The luminescent-layer-forming coating liquid for use in this embodiment contains quantum dots 22, each quantum dot 22 being surrounded by organic ligands 21 (see FIG. 2), and it is usually a dispersion of quantum dots 22, each quantum dot 22 being surrounded by organic ligands 21, in a solvent. The components of the luminescent-layer-forming coating liquid will be described below.

### (i) Quantum Dot 22

In this embodiment, any quantum dot can be used as the quantum dot 22 without limitation, as long as it emits fluorescent or phosphorescent light. It is particularly preferred that a so-called compound semiconductor be contained in the quantum dot 22. Examples of compound semiconductors include compounds of Group IV, Groups I and VII, Groups II and VI, Groups II and V, Groups III and VI, Groups III and V, Groups IV and VI, Groups I, III and VI, Groups II, IV and VI, and Groups II, IV and V. Specific examples of these compounds include ZnS, ZnSe, ZnTe, CdS, CdSe, CdTe, HgS, HgSe, HgTe, AlN, AIP, AlAs, AlSb, GaN, GaP, GaAs, GaSb, GaSe, InN, InP, InAs, InSb, TlN, TlP, TlAs, TlSb, PbS, PbSe and PbTe, and mixtures of these compounds. Of these compound semiconductors, CdSe is preferred from the viewpoint of flexibility and optical properties.

The quantum dot 22 may consist only of a core part 22c made of a semiconductor fine particle, or consist of a core part 22c made of a semiconductor fine particle and a shell part 22s covering the core part 22c, made from a material having a greater band gap than the semiconductor fine particle (see FIG. 2A). Preferably, the quantum dot 22 has the core part 22c and the shell part 22s. Namely, it is preferred that the quantum dot 22 be a core-shell-type quantum dot having a core-shell structure. This is because a quantum dot 22 having a core-shell structure has higher stability.

A fine particle of any of the above-enumerated compound semiconductors is favorably used as the semiconductor fine particle for the core part 22c of the quantum dot 22.

Although any material can be used for the shell part 22s without limitation, as long as it has a greater band gap than the semiconductor fine particle, the above-enumerated compound semiconductors are favorably used for the shell part 22s like for the semiconductor fine particle serving as the core part 22c. The compound semiconductor to be used for the shell part 22s may be either the same as, or different from, the compound semiconductor to be used for the core part 22c.

Examples of the core-shell-type quantum dot include CdSe (core part 22c)/CdS (shell part 22s), CdSe/ZnS, CdTe/CdS, InP/ZnS, GaP/ZnS, Si/ZnS, InN/GaN, InP/CdSSe, InP/ZnSeTe, GaInP/ZnSe, GaInP/ZnS, Si/AlP, InP/ZnSTe, GaInP/ZnSTe, and GaInP/ZnSSe. Of these quantum dots, CdSe/ZnS is preferred from the viewpoint of flexibility and optical properties.

Examples of the shape of the quantum dot 22 include spheres, rods, and discs.

The shape of the quantum dot 22 can be confirmed by a transmission electron microscope (TEM).

It is preferred that the particle diameter of the quantum dot 22 be less than 20 nm, particularly from 1 to 15 nm, and more particularly from 1 to 10 nm. This is because the quantum size effect may not be obtained when the quantum dot 22 has an excessively large particle diameter.

Since the quantum dot 22 emits spectrum that varies depending on its particle diameter, the particle diameter of the quantum dot 22 is selected according to the desired color. For example, in the case of CdSe/ZnS quantum dot of core/shell type, the emission spectrum of the quantum dot shifts to the longer wavelength side as the particle diameter of the quantum dot is increased, and the quantum dot emits red spectrum when its particle diameter is 5.2 nm and blue spectrum when 1.9 nm.

Further, it is preferred that the particle diameter distribution of the quantum dots 22 be relatively narrow.

The particle diameter of the quantum dot 22 can be determined using a transmission electron microscope (TEM), a powder X-ray diffraction (XRD) pattern, or UV/Vis absorption spectrum.

The content of the quantum dots 22 surrounded by organic ligands 21 in the luminescent-layer-forming coating liquid is preferably from 50 to 100% by weight, more preferably from 60 to 100% by weight, of the total weight of the solid materials (100% by weight) in the luminescent-layer-forming coating liquid. This is because when the quantum dot content is excessively low, the luminescent layer may not emit light satisfactorily, while the quantum dot content is excessively high, it may be difficult to form the luminescent layer 3.

As for the method for synthesizing the quantum dot 22, reference can be made to Published Japanese Translations No. 2005-522005 and No. 2006-520077 of PCT patent applications, Japanese Laid-Open Patent Publication No. 2007-21670, and so forth.

The organic ligands 21 attached to the surface of the quantum dot 22 can be replaced with other type of organic ligands 21. For example, the organic ligands 21 attached to the surfaces of the quantum dots 22 can be replaced with the desired organic ligands by heating the quantum dots 22 having the organic ligands 21 and a large amount of the desired organic ligands with which the organic ligands 21 will be replaced, while mixing them in an atmosphere of an inert gas. The organic ligands 21 attached to the surfaces of the quantum dots 22 can also be replaced with e.g., a silane coupling agent by mixing the quantum dots 22 having the organic ligands 21 with a large amount of the silane coupling agent. It is preferred that the above treatment for replacing the organic ligands 21 with a silane coupling agent be carried out at around room temperature.

As for the method for replacing the organic ligands 21, reference can be made to Japanese Laid-Open Patent Publication No. 2007-21670.

Examples of commercially available quantum dots 22 that have organic ligands 21, such as TOPO, attached to their surfaces, and that can be used herein include fluorescent semiconductor nanocrystal “Evidot” manufactured by evident TECHNOLOGIES CO.

### (ii) Organic Ligand 21

Organic ligands 21 usually attached to quantum dots 22 can be used for the organic ligand 21 in this embodiment. Examples of organic ligands 21 useful herein include alkylphosphines such as tri-n-octylphosphine (TOP), alkylphosphine oxides such as tri-n-octylphosphine oxide (TOPO), alkylphosphinic acids such as alkylphosphinic acid and tris-hydroxylpropylphosphine (tHPP), pyridine, furan, and hexadecylamine.

A silane coupling agent can also be used as the organic ligand 21. Since the molecular design of silane coupling agents is relatively easy, it is easy to make quantum dots dispersible in solvents and to control the reactivity of quantum dots by the use of silane coupling agents having different functional groups. Further, the organic-ligand-removing step that will be described later can achieve removal of various functional groups from silane coupling agents. By removing the functional groups, better life characteristics can be obtained.

Silane coupling agents useful herein include (1) chloro- or alkoxy-silanes, and (2) reactive silicones.

Silicon compounds represented by the following general formula:

YₙSiX₍₄₋ₙ₎

(wherein Y represents an alkyl group, a fluoroalkyl group, vinyl group, amino group, phenyl group or epoxy group, X represents an alkoxyl group, an acetyl group or a halogen, and n is an integer of 0 to 3) are favorably used as the above silane coupling agents (1). X and Y in the silicon compounds represented by the above formula are removed in the organic-ligand-removing step that will be described later. Preferably, the group denoted by Y has 1 to 20 carbon atoms, and the alkoxyl group denoted by X is methoxyl, ethoxyl, propoxyl, or butoxyl group. Specifically, the silicon compounds described in Japanese Laid-Open Patent Publication No. 2000-249821 can be used as the silicon compounds represented by the above formula.

The above reactive silicones (2) include compounds having a structure represented by the following chemical formula:

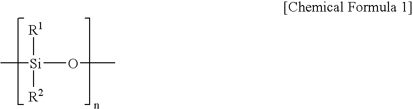

In the above formula, n is an integer of 2 or more, and R¹ and R² independently represent a substituted or unsubstituted alkyl, alkenyl, aryl, or cyanoalkyl group having 1 to 10 carbon atoms. The reactive silicones having the above structure contain not more than 40% by mole of vinyl group, phenyl group, or a halogenated phenyl group. A reactive silicone having the above structure in which both R¹ and R² are methyl group is preferred because it has the lowest surface energy, and its methyl group content is preferably 60% by mole or more. Further, the reactive silicones having the above structure have at least one reactive group, such as hydroxyl group, in a molecular chain situated at the end of the main chain or in a side chain. R¹ and R² in the reactive silicones are removed in the organic-ligand-removing step that will be described later.

(iii) Solvent

Any solvent can be used in the luminescent-layer-forming coating liquid to be used in this embodiment, as long as it can be mixed with the quantum dots 22 surrounded by organic ligands 21. Examples of such solvents include aromatic hydrocarbon solvents such as xylene, toluene, cyclohexylbenzene, dihydrobenzofuran, trimethylbenzene and tetramethylbenzene, aromatic heterocyclic compounds such as pyridine, pyrazine, furan, pyrrole, thiophene and methylpyrrolidone, and aliphatic hydrocarbon solvents such as hexane, pentane, heptane and cyclohexane. These solvents may be used either singly or in combination.

### (iv) Others

A variety of additives can be added to the luminescent-layer-forming coating liquid to be used in this embodiment. For example, if an ink jetting process is employed to form the luminescent layer 3, a surface-active agent, or the like may be added to the luminescent-layer-forming coating liquid for the purpose of improving ink-jetting characteristics.

Further, in this embodiment, to form a luminescent layer 3 consisting of three layers of red, green and blue, the three primary colors, luminescent-layer-forming coating liquids for red, green and blue layers are used. As mentioned above, since the quantum dot 22 emits spectrum that varies depending on its particle diameter, the particle diameter of the quantum dot 22 is controlled according to the desired color.

### (2) Method for Forming Luminescent Layer 3

In this embodiment, the luminescent layer 3 is formed on the substrate 1 on which the first electrode layer 2 has been formed, by applying the luminescent-layer-forming coating liquid.

Examples of processes that can be employed to apply the luminescent-layer-forming coating liquid include spin coating, ink jetting, casting, LB process, dispenser process, micro-gravure coating, gravure coating, bar coating, roll coating, wire bar coating, dip coating, blade coating, spay coating, flexographic printing, offset process, screen printing, and gravure printing.

The luminescent layer 3 may be formed either wholly or pattern-wise on the surface of the substrate 1 on which the first electrode layer 2 has been formed.

Conventional patterning processes can be used to pattern the luminescent layer 3. Examples of patterning processes useful herein include photolithographic processes and processes using a layer containing a photocatalyst.

The above photolithographic processes include etching processes and lift-off processes.

Conventional etching processes can be used in this embodiment. For example, an etching process useful herein comprises the steps of forming a luminescent layer 3 on a substrate 1 on which a first electrode layer 2 has been formed, forming a photoresist layer on the luminescent layer 3, patterning the photoresist layer, etching those portions of the luminescent layer 3 that have been bared by removing the photoresist layer, and removing the remaining portions of the photoresist layer.

The above etching process is described in detail in Japanese Laid-Open Patent Publication No. 2004-6231, for example.

Conventional lift-off processes can also be used in this embodiment. For example, a lift-off process useful herein comprises the step of forming a photoresist layer on a substrate 1 on which a first electrode layer 2 has been formed, patterning the photoresist layer, forming a luminescent layer 3 on the substrate 1 having thereon the patterned photoresist layer, and lifting off the luminescent layer 3 by removing the remaining photoresist layer.

An example of the above-described processes using a layer containing a photocatalyst is a process comprising the step of forming, on a substrate 1 on which a first electrode layer 2 has been formed, a wettability-varying layer that contains a photocatalyst and varies in wettability due to the photocatalytic action that is accompanied by the application of energy, the step of forming, on the wettability-varying layer surface, a wettability-varying pattern consisting of lyophilic regions and lyophobic regions by applying energy pattern-wise to the wettability-varying layer, and the step of forming a luminescent layer 3 on the lyophilic regions. Another example of the processes using a photocatalyst-containing layer is a process comprising the step of forming, on a substrate 1 on which a first electrode layer 2 has been formed, a wettability-varying layer that varies in wettability due to the photocatalytic action that is accompanied by the application of energy, the step of forming, on the wettability-varying layer surface, a wettability-varying pattern consisting of lyophilic regions and lyophobic regions by applying energy pattern-wise to the wettability-varying layer, after placing a photocatalytic treatment plate composed of a base and a photocatalytic treatment layer containing at least a photocatalyst, formed on the base, above the wettability-varying layer, leaving such a gap that the photocatalytic action that is accompanied by the application of energy can reach the wettability-varying layer, and the step of forming a luminescent layer 3 on the lyophilic regions.

The above processes using a layer containing a photocatalyst are described in detail in Japanese Laid-Open Patent Publications No. 2006-310036 and No. 2005-300926, for example.

The luminescent layer 3 can have any thickness without limitation, as long as it provides space to electrons and holes for recombination by which it can emit light. For example, the thickness of the luminescent layer 3 is from about 1 to 200 nm, preferably from 1 nm to 100 nm. This is because when the luminescent layer 3 has an excessively great thickness, neither UV nor ozone can reach the inside of the luminescent layer 3 in the UV-ozone treatment, which makes the removal of the organic ligands 21 existing on the inside of the luminescent layer 3 difficult, or which leads to an increase of the time needed to remove the organic ligands 21.

### (3) Substrate 1

The substrate 1 to be used in this embodiment may be either transparent or non-transparent. For example, when the EL device shown in FIG. 1(c) is of bottom emission type, it is preferred that the substrate 1 be transparent. On the other hand, when the EL device shown in FIG. 1(c) is of top emission type, the substrate 1 need not be transparent. When the EL device shown in FIG. 1(c) is of the type that light is extracted from both sides of the device, it is preferred that the substrate 1 be transparent.

Examples of materials useful for the substrate 1 having transparency include inorganic materials such as glass, and transparent resins.

Any transparent resin can be used in this embodiment without limitation as long as it can form a film, and transparent resins having high transparency and relatively high resistance to solvents and heat are preferred. Examples of such transparent resins useful herein include polyether sulfone, polyethylene terephthalate (PET), polycarbonate (PC), polyether ether ketone (PEEK), polyvinyl fluoride (PVF), polyacrylate (PA), polypropylene (PP), polyethylene (PE), amorphous polyolefins, and fluororesins.

### (4) First Electrode Layer 2

The first electrode layer 2 in this embodiment may serve either as the anode or as the cathode. Generally, the production of an EL device progresses stably when component layers are deposited from the anode side. It is therefore preferred that the first electrode layer 2 be the anode.

A conductive material whose work function is great is favorably used for the anode to make the injection of holes into the anode easy. On the other hand, a conductive material whose work function is small is favorably used for the cathode to make the injection of electrons into the cathode easy. Conductive materials usually used for electrodes can be used herein.

It is particularly preferred that the conductive material for the first electrode layer 2 be resistant to UV-ozone cleaning. In this embodiment, the luminescent layer 3 formed on the first electrode layer 2 is subjected to UV-ozone cleaning, as illustrated in FIG. 1(b). It is therefore preferred that the conductive material to be used to form the first electrode layer 2 be resistant to the UV-ozone cleaning.

Examples of the conductive material resistant to the UV-ozone cleaning include metallic materials and inorganic compounds.

The first electrode layer 2 may be either transparent or non-transparent, and it depends on the side from which light will be extracted. For example, when the EL device shown in FIG. 1(c) is of bottom emission type, it is preferred that the first electrode layer 2 be transparent. On the other hand, when the EL device shown in FIG. 1(c) is of top emission type, the first electrode layer 2 need not be transparent. When the EL device shown in FIG. 1(c) is of the type that light is extracted from both sides of the device, it is preferred that the first electrode layer 2 be transparent.

As mentioned above, the transparent conductive material for the first electrode layer 2 is preferably one resistant to the UV-ozone cleaning, such as In—Zn—O (IZO), In—Sn—O (ITO), Zn—O—Al, or Zn—Sn—O. Even when the first electrode layer 2 need not be transparent, it is preferred that the conductive material be resistant to the UV-ozone cleaning, as mentioned above, and metals can be used. Specific examples of metals useful herein include Au, Ta, W, Pt, Ni, Pd, Cr, Al alloys, Ni alloys, and Cr alloys.

It is preferred that the resistance of the first electrode layer 2 be relatively low whether the first electrode layer 2 serves either as the anode or as the cathode.

Conventional processes of electrode film deposition can be used to form the first electrode layer 2. Examples of such processes include sputtering, ion plating, and vacuum vapor deposition. To pattern the first electrode layer 2, a photolithographic process can be used.

### 2. Organic-Ligand-Removing Step

The organic-ligand-removing step in this embodiment is the step of removing the organic ligands 21 by subjecting the luminescent layer 3 to UV-ozone cleaning.

The UV-ozone cleaning can be conducted in any manner as long as the organic ligands 21 can be removed.

An atmosphere in which the luminescent layer 3 is irradiated with ultraviolet light may be air, ozone-containing oxygen, ozone-containing air, or the like.

While the luminescent layer 3 is irradiated with ultraviolet light, the substrate 1 having thereon the luminescent layer 3 may be heated. This is because, by doing so, the organic ligands 21 can be removed from the luminescent layer 3 efficiently. The heating may be conducted at a temperature of about 60 to 400° C.

If the organic ligand 21 is a silane coupling agent, the substrate 1 is not heated so as not to raise the reactivity of the silane coupling agent.

Generally, the entire surface of the substrate 1 having thereon the luminescent layer 3 is subjected to the UV-ozone cleaning.

That the organic material has been removed can be confirmed by Fourier transform infrared spectroscopic analysis (FT-IR), time-of-flight secondary ion mass spectrometric analysis (TOF-SIM), or the like.

### 3. Second-Electrode-Layer-Forming Step

The second-electrode-layer-forming step in this embodiment is the step of forming the second electrode layer 4 on the luminescent layer 3 from which the organic ligands 21 have been removed.

As long as the second electrode layer 4 faces the first electrode layer 2, it can fulfill its purpose whether it serves either as the anode or as the cathode.

Any material can be used to form the second electrode layer 4 without limitation as long as it is electrically conductive. For example, to extract light from the second electrode layer 4 side, it is preferable to make the second electrode layer 4 transparent. On the other hand, to extract light from the first electrode 2 side, the second electrode layer 4 need not be transparent. Since conductive materials useful for the second electrode layer 4 are the same as those described as being useful for the first electrode layer 2, they are not described here any more.

The method for forming the second electrode layer 4 and the method for patterning the second electrode layer 4 are also the same as the above-described method for forming the first electrode layer 2 and method for patterning the first electrode layer 2, so that they are not described here any more.

### 4. Hole-Injection-Transporting-Layer-Forming Step

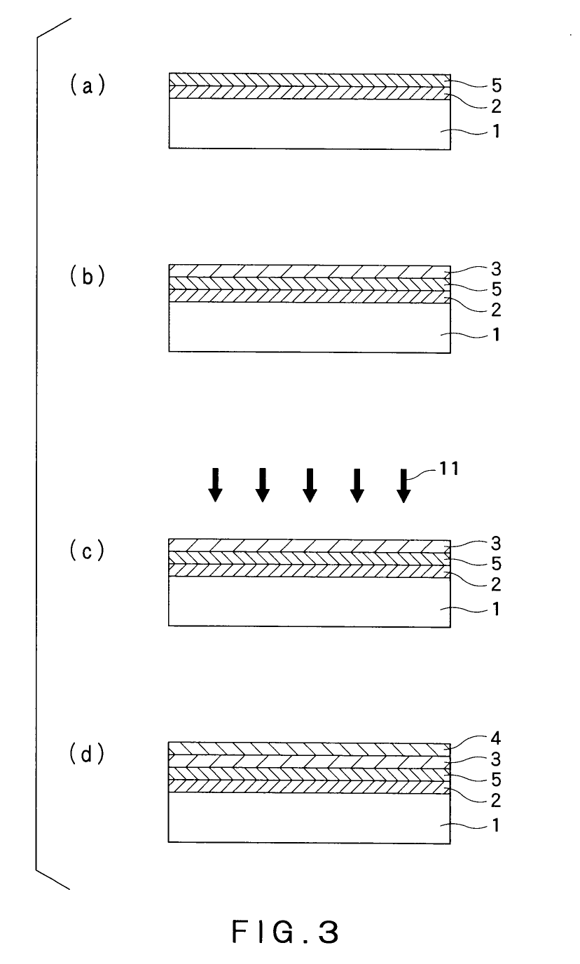

In this embodiment, the step of forming, on the first electrode layer 2, a hole injection transporting layer 5 having the property of injecting holes may be performed between the first-electrode-layer-forming step and the luminescent-layer-forming step, as illustrated in FIGS. 3(a) to 3(d) (see FIGS. 3(a) and 3(b)). The hole injection transporting layer 5 stabilizes the injection of holes into the luminescent layer 3 and makes the transportation of holes smooth, which leads to enhancement of emission efficiency.

The hole injection transporting layer 5 may be any of the following layers: a hole injection layer having the function of stably injecting, into the luminescent layer 3, holes injected from the anode; a hole transporting layer having the function of transporting, to the luminescent layer 3, holes injected from the anode; a layer composed of the hole injection layer and the hole transporting layer; and a single layer having both the function of injecting holes and the function of transporting holes.

The material for the hole injection transporting layer 5 is selected according to the function required for the hole injection transporting layer 5, and an inorganic material is particularly preferred. In this embodiment, the luminescent layer 3 formed on the hole injection transporting layer 5 is subjected to the UV-ozone cleaning, as illustrated in FIG. 3(c). It is therefore preferred that the material for the hole injection transporting layer 5 be resistant to the UV-ozone cleaning, and an inorganic material is suited for the hole injection transporting layer 5. Layers of inorganic materials are stable to the UV-ozone cleaning.

Any hole injection material can be used without limitation to form the hole injection layer as long as it can stabilize the injection of holes into the luminescent layer 3, and inorganic materials having the property of injecting holes are preferred, as mentioned above. Examples of inorganic materials having the property of injecting holes include oxides such as vanadium oxide, molybdenum oxide, ruthenium oxide, and aluminum oxide. These materials may be used either singly or in combination.

The hole injection layer can have any thickness as long as it can fully exhibit its function. Specifically, the thickness of the hole injection layer is preferably from 1 to 200 nm, more preferably from 5 to 100 nm.

Any hole transporting material can be used without limitation to form the hole transporting layer as long as it can stably transport, into the luminescent layer 3, holes injected from the anode, and inorganic materials having the property of transporting holes are preferred, as mentioned above. Examples of inorganic materials having the property of transporting holes include Lewis acid compounds such as ferric chloride, aluminum chloride, gallium chloride, indium chloride, antimony pentachloride, molybdenum trioxide (MoO₃), and vanadium pentaoxide (V₂O₅). Of these compounds, metallic oxides such as molybdenum trioxide (MoO₃) and vanadium pentaoxide (V₂O₅) are favorably used.

The hole transporting layer can have any thickness as long as it can fully exhibit its function. Specifically, the thickness of the hole transporting layer is preferably from 1 to 200 nm, more preferably from 5 to 100 nm.

Such a process as vacuum vapor deposition can be employed to form the hole injection transporting layer 5.

### 5. Electron-Injection-Transporting-Layer-Forming Step

In this embodiment, the step of forming an electron injection transporting layer on the luminescent layer 3 may be performed after the luminescent-layer-forming step. The electron injection transporting layer stabilizes the injection of electrons into the luminescent layer 3 and makes the transportation of electrons smooth, which leads to enhancement of emission efficiency.

The electron injection transporting layer may be any of the following layers: an electron injection layer having the function of stably injecting, into the luminescent layer 3, electrons injected from the cathode; an electron transporting layer having the function of transporting, to the luminescent layer 3, electrons injected from the cathode; a layer composed of the electron injection layer and the electron transporting layer; and a single layer having both the function of injecting electrons and the function of transporting electrons.

Any electron injection material can be used for the electron injection layer, as long as it can stabilize the injection of electrons into the luminescent layer 3. Examples of such electron injection materials include single alkali or alkali earth metals such as Ba, Ca, Li, Cs, Mg and Sr, alkali metal alloys such as aluminum-lithium alloys, oxides of alkali or alkali earth metals such as magnesium oxide and strontium oxide, fluorides of alkali or alkali earth metals such as magnesium fluoride, calcium fluoride, strontium fluoride, barium fluoride, lithium fluoride and cesium fluoride, and organic alkali metal complexes such as polymethyl methacrylate polystyrene sodium sulfonate. The electron injection layer may also be a multi-layered film of two or more of the above-enumerated materials, e.g., Ca/LiF.

The electron injection layer can have any thickness as long as it can fully exhibit its function. Specifically, the thickness of the electron injection layer is preferably from 0.1 to 200 nm, more preferably from 0.5 to 100 nm.

Any electron transporting material can be used for the electron transporting layer, as long as it can stably transport, to the luminescent layer 3, electrons injected from the cathode. Examples of such electron transporting materials include phenanthroline derivatives such as bathocuproine (BCP) and bathophenanthroline (Bphen), triazole derivatives, oxadiazole derivatives, and alumiquinolinol complexes such as tris(8-quinolinol)aluminum complex (Alq₃).

The electron transporting layer can have any thickness as long as it can fully exhibit its function. Specifically, the thickness of the electron transporting layer is preferably from 1 to 100 nm, more preferably from 1 to 50 nm.

Examples of materials for forming single layers having both the function of injecting electrons and the function of transporting electrons include electron transporting materials doped with an alkali or alkali earth metal such as Li, Cs, Ba or Sr. Examples of electron transporting materials include phenanthroline derivatives such as bathocuproine (BCP) and bathophenanthroline (Bphen). The molar ratio of the electron transporting material to the dopant metal is preferably in the range of 1:1 to 1:3, more preferably in the range of 1:1 to 1:2. The electron transporting materials doped with an alkali or alkali earth metal give relatively high mobility to electrons and have higher transmittance than single metals.

The single layer having both the function of injecting electrons and the function of transporting electrons can have any thickness as long as it can fully exhibit its function. Specifically, the thickness of such a layer is preferably from 0.1 to 100 nm, more preferably from 0.1 to 50 nm.

Either a dry process such as vacuum vapor deposition or a wet process such as spin coating may be employed to form the electron injection transporting layer.

### 6. Insulating-Layer-Forming Step

In this embodiment, the step of forming an insulating layer in the openings in the patterned first electrode layer 2 formed on the substrate 1 may be performed prior to the luminescent-layer-forming step. The insulating layer is for preventing conduction between the adjacent patterns of the first electrode layer 2, and between the first electrode layer 2 and the second electrode layer 4. The openings filled with the insulating layer form non-luminescent regions.

The insulating layer is formed in the openings in the patterned first electrode layer 2 on the substrate 1, usually in such a manner that it covers the ends of the patterns of the first electrode layer 2.

Any material can be used to form the insulating layer as long as it has insulating properties. Examples of insulating materials useful herein include photosensitive polyimide resins, photo-setting resins such as acrylic resins, thermosetting resins, and inorganic materials.

A conventional process such as a photolithographic or printing process can be used to form the insulating layer.

### II. Second Embodiment

The second embodiment of the process of the invention, for producing an electroluminescent device, is characterized by comprising the step of preparing a substrate 1, the step of forming a first electrode layer 2 on the substrate 1, the step of forming a luminescent layer 3 on the first electrode layer 2 by applying, to the first electrode layer 2, a luminescent-layer-forming coating liquid containing quantum dots 22, each quantum dot 22 being surrounded by organic ligands 21, the step of removing the organic ligands 21 from the quantum dots 22 by plasma irradiation of the luminescent layer 3 (by exposing the luminescent layer 3 to plasma 16), and the step of forming a second electrode layer 4 on the luminescent layer 3 in which the organic ligands 21 have been removed from the quantum dots 22.

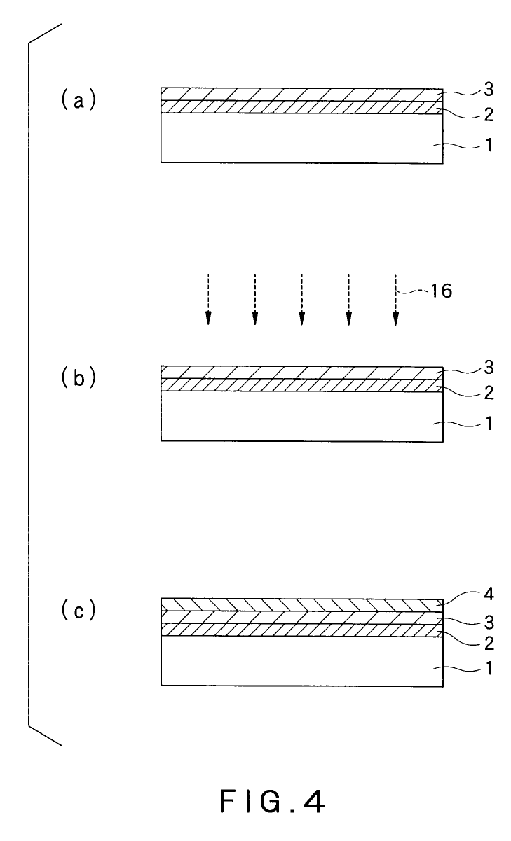

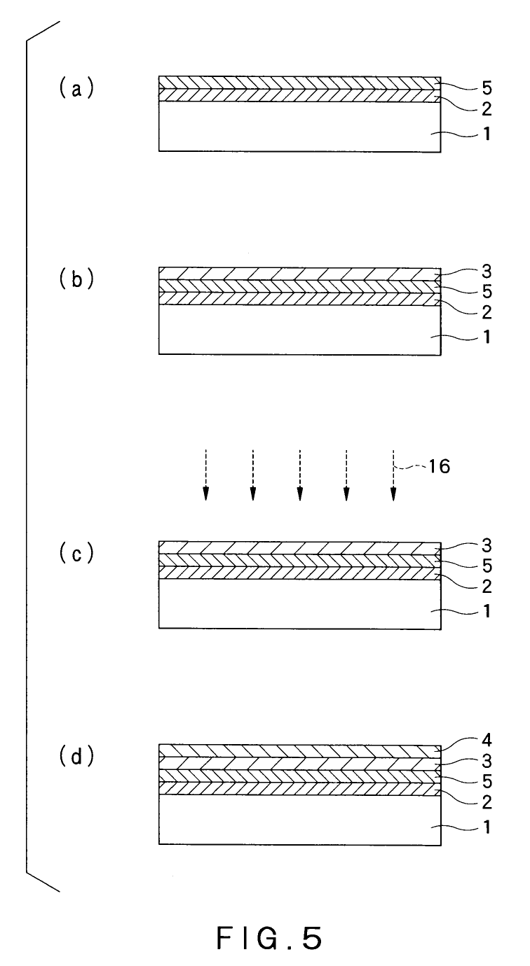

Layers, etc. in the second embodiment shown in FIGS. 4 and 5 are denoted by the reference numerals that are used to denote the corresponding layers, etc. in the first embodiment shown in FIGS. 1 to 3, and they will not be explained in detail any more.

Plasma 16 irradiation achieves removal of various types of organic materials with ease. According to this embodiment, plasma irradiation of the luminescent layer 3 is employed to remove the organic ligands 21 from the luminescent layer 3, so that removal of organic ligands of various types can be achieved. It is thus possible to obtain an EL device having high efficiency and a long life.

Since the substrate-preparing step, the first-electrode-layer-forming step, the luminescent-layer-forming step, and the second-electrode-layer-forming step in this embodiment are the same as those in the first embodiment, they will not be described here any more. The other steps in the process for producing an EL device according to the second embodiment will be described below.

### 1. Organic-Ligand-Removing Step

The organic-ligand-removing step in this embodiment is the step of removing the organic ligands 21 by plasma irradiation of the luminescent layer 3 (by exposing the luminescent layer 3 to plasma 16).

The plasma irradiation of the luminescent layer 3 can be conducted in any manner as long as the organic ligands 21 can be removed from the luminescent layer 3.

Reactive gases that are conventionally used to generate plasmas can be used to create the plasma 16 in this embodiment. Particularly preferred reactive gases are those ones that make it possible to remove the organic ligands efficiently. Such reactive gases include combinations of gases selected from fluorine- or fluorine-compound-containing gases, chlorine- or chlorine-compound-containing gases, oxygen, argon, and so forth.

Generally, the entire surface of the luminescent layer 3 formed on the substrate 1 is subjected to the above plasma irradiation treatment.

That the organic material has been removed can be confirmed by Fourier transform infrared spectroscopic analysis (FT-IR), time-of-flight secondary ion mass spectrometric analysis (TOF-SIM), or the like.

### 2. Other Steps

In the meantime, the step of forming, on the first electrode layer 2, a hole injection transporting layer 5 having the property of injecting holes may be performed between the first-electrode-layer-forming step and the luminescent-layer-forming step in this embodiment, as illustrated in FIGS. 5(a) to 5(d), like in the first embodiment. The hole injection transporting layer 5 stabilizes the injection of holes into the luminescent layer 3 and makes the transportation of holes smooth, which leads to enhancement of emission efficiency. Specifically, the hole injection transporting layer 5 in this embodiment is the same as the hole injection transporting layer 5 in the first embodiment.

Moreover, the step of forming an electron injection transporting layer, the step of forming an insulating layer, etc. may also be performed as in the first embodiment.

### III. Third Embodiment

The third embodiment of the process of the invention, for producing an EL device, is characterized by comprising the step of preparing a substrate 1, the step of forming a first electrode layer 2 on the substrate 1, the step of forming a luminescent layer 3 on the first electrode layer 2 by applying, to the first electrode layer 2, a luminescent-layer-forming coating liquid containing quantum dots 22, each quantum dot 22 being surrounded by organic ligands 21, the step of placing, above the luminescent layer 3, a photocatalytic treatment layer 33 containing at least a photocatalyst, the step of removing the organic ligands 21 from the quantum dots 22 by applying energy to the photocatalytic treatment layer 33, and the step of forming a second electrode layer 4 on the luminescent layer 3 in which the organic ligands 21 have been removed from the quantum dots 22.

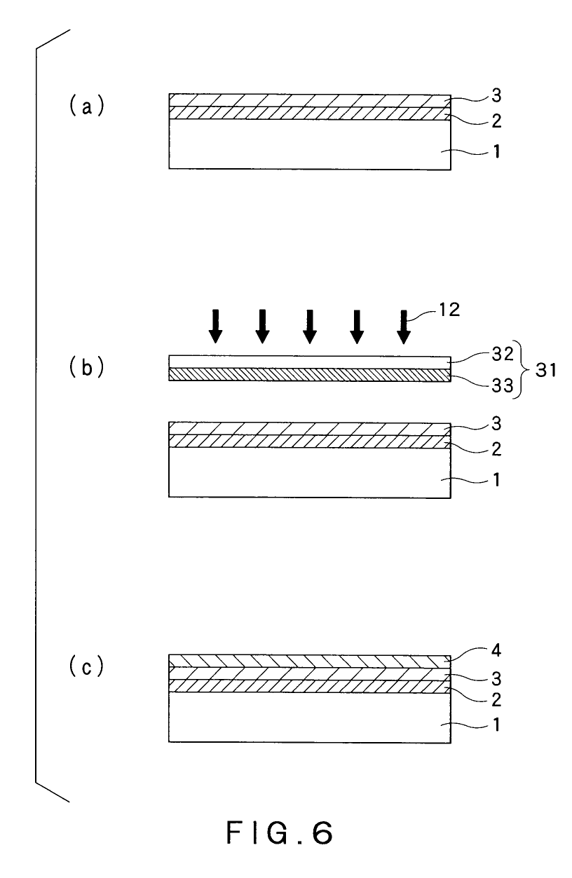

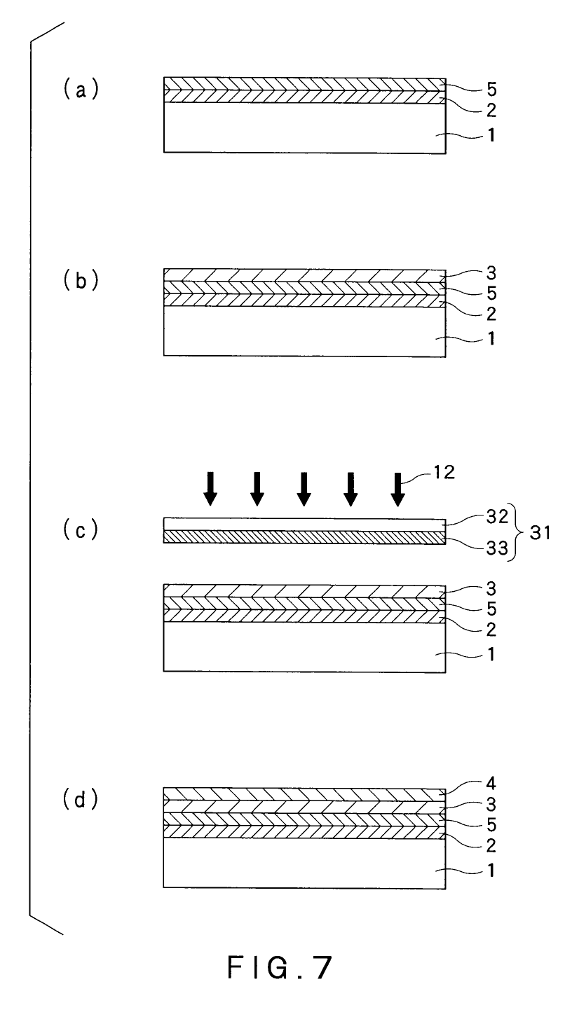

Layers, etc. in the third embodiment shown in FIGS. 6 and 7 are denoted by the reference numerals that are used to denote the corresponding layers, etc. in the first embodiment shown in FIGS. 1 to 3, and they will not be explained in detail any more.

FIG. 6 is a flow chart showing a process for producing an EL device according to this embodiment. A substrate 1 is first prepared (substrate-preparing step). Next, a first electrode layer 2 is formed on the substrate 1 (first-electrode-layer-forming step). And then a luminescent-layer-forming coating liquid containing quantum dots 22, each quantum dot 22 being surrounded by organic ligands 21, is applied to the first electrode layer 2 to form a luminescent layer 3 (FIG. 6(a), luminescent-layer-forming step).

Next, as illustrated in FIG. 6(b), a photocatalytic treatment plate 31 is prepared by forming a photocatalytic treatment layer 33 on a base 32. Subsequently, the photocatalytic treatment plate 31 is placed above the substrate 1, leaving a gap, with the photocatalytic treatment layer 33 in the former facing to the luminescent layer 3 on the latter (photocatalytic-treatment-layer-placing step). The gap between the photocatalytic treatment layer 33 and the luminescent layer 3 is such a distance that the photocatalytic action can reach the luminescent layer 3 when the photocatalytic treatment layer 33 is irradiated with ultraviolet light 12 (application of energy to the photocatalytic treatment layer 33).

Next, the photocatalytic treatment layer 33 is irradiated with ultraviolet light 12 (energy is applied to the photocatalytic treatment layer 33). By this, the photocatalyst contained in the photocatalytic treatment layer 33 acts to remove the organic ligands 21 from the luminescent layer 3 (FIG. 6(b), organic-ligand-removing step).

Although how a photocatalyst acts is not clear, the following seems to occur when energy is applied: a photocatalyst causes redox to generate active oxygen species such as super oxide radical (.O₂—) and hydroxyl radical (.OH), and these active oxygen species cause an organic material to change in chemical structure. It is assumed that, in this embodiment, such active oxygen species act on the organic ligands 21 in the luminescent layer 3 situated in the vicinity of the photocatalytic treatment layer 33.

Next, the second electrode layer 4 is formed on the luminescent layer 3 (FIG. 6(c), second-electrode-layer-forming step).

The treatment using the photocatalytic treatment plate 31 makes it possible to remove various types of organic materials with ease. This embodiment, therefore, can achieve removal of organic ligands 21 of various types. It is thus possible to obtain an EL device having high efficiency and a long life. Even when a relatively small amount of energy such as ultraviolet light is applied in this treatment, the organic ligands 21 can be removed.

Since the luminescent-layer-forming step and the second-electrode-layer-forming step in this embodiment are the same as those in the first embodiment, they are not described here any more. The other steps in the process for producing an EL device according to this embodiment will be described below.

### 1. Photocatalytic-Treatment-Layer-Placing Step and Organic-Ligand-Removing Step

The photocatalytic treatment plate 31, the placement of the photocatalytic treatment layer 33 above the luminescent layer 3, and the application of energy will be described hereinafter.

### (1) Photocatalytic Treatment Plate 31

The photocatalytic treatment plate 31 for use in this embodiment comprises a base 32 and a photocatalytic treatment layer 33 formed on the base 32. The photocatalytic treatment layer 33 and the base 32 will be described below.

### (Photocatalytic Treatment Layer 33)

The photocatalytic treatment layer 33 in this embodiment contains a photocatalyst. Any layer containing a photocatalyst can be used as the photocatalytic treatment layer 33 as long as the photocatalyst acts on the organic ligands 21 in the luminescent layer 3. The photocatalytic treatment layer 33 may be made up of a photocatalyst and a binder, or made from a single photocatalyst. A photocatalytic treatment layer 33 made only from a photocatalyst has higher efficiency in removing the organic ligands 21 from the luminescent layer 3 and takes a shorter time to remove the organic ligands 21, so that it is advantageous from the viewpoint of cost. A photocatalytic treatment layer 33 made up of a photocatalyst and a binder has the advantage that it can be formed easily.

Examples of the photocatalyst include titanium dioxide (TiO₂), zinc oxide (ZnO), tin oxide (SnO₂), strontium titanate (SrTiO₃), tungsten oxide (WO₃), bismuth oxide (Bi₂O₃), and iron oxide (Fe₂O₃), which are known as photo-semiconductors. These photocatalysts may be used either singly or in combination.

Of the above photocatalysts, titanium dioxide has high band gap energy, is chemically stable, is non-toxic, and is easily available, so that it is favorably used in this embodiment. Titanium dioxide takes two forms, anatase and rutile. Although titanium dioxide in either form can be used herein, anatase is preferred. Titanium dioxide in the form of anatase is excited at a wavelength of below 380 nm.

Commercially available titanium dioxides in the form of anatase include anatase titania sols that are deflocculated with hydrochloric acid, STS-02 (mean particle diameter: 7 nm) and ST-K01 manufactured by Ishihara Sangyo Kaisha, Ltd., Japan, and anatase titania sol that is deflocculated with nitric acid, TA-15 (mean particle diameter: 12 nm) manufactured by Nissan Chemical Industries, Ltd., Japan.

Since a photocatalyst having a smaller particle diameter causes photocatalytic reaction more effectively, the smaller in particle diameter is the better. Specifically, it is preferred that the mean particle diameter of the photocatalyst be 50 nm or less, particularly 20 nm or less.

When the photocatalytic treatment layer 33 is made up of a photocatalyst and a binder, the binder is preferably a material having such high bond energy that its main chain is not decomposed by the photoexcitation of the photocatalyst. Examples of such binders include organopolysiloxanes such as (1) organopolysiloxanes of high strength, obtained by hydrolyzing and condensation-polymerizing chloro- or alkoxy-silanes by a sol-gel reaction or the like, and (2) organopolysiloxanes obtained by crosslinking reactive silicones excellent in water and oil repellency.

Preferred herein as the above organopolysiloxanes (1) are hydrolysis or co-hydrolysis condensates of one, or two or more, of silicon compounds represented by the following general formula:

YₙSiX₍₄₋ₙ₎

wherein Y represents an alkyl group, a fluoroalkyl group, vinyl group, amino group, phenyl group, or epoxy group, X represents an alkoxyl group, acetyl group, or a halogen, and n is an integer of 0 to 3. Preferably, the group represented by Y has 1 to 20 carbon atoms, and the alkoxyl group represented by X is methoxyl, ethoxyl, propoxyl, or butoxyl group. Specifically, the silicon compounds described in Japanese Laid-Open Patent Publication No. 2000-249821, and so forth can be used as the silicon compounds of the above formula.

The reactive silicones useful for obtaining the above organopolysiloxanes (2) include compounds having a structure represented by the following chemical formula.

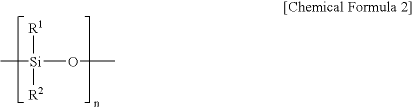

In the above formula, n is an integer of 2 or more, and R¹ and R² independently represent a substituted or unsubstituted alkyl, alkenyl, aryl, or cyanoalkyl group having 1 to 10 carbon atoms. The reactive silicones having the above structure contain not more than 40% by mole of vinyl group, phenyl group, or a halogenated phenyl group. A reactive silicone having the above structure in which both R¹ and R² are methyl group is preferred because it has the lowest surface energy, and its methyl group content is preferably 60% by mole or more. Further, the reactive silicones having the above structure have at least one reactive group, such as hydroxyl group, in a molecular chain situated at the end of the main chain, or in a side chain.

The above organopolysiloxanes may be mixed with stable organosilicone compounds that do not crosslink, such as dimethylpolysiloxane.

Amorphous silica precursors can be used for the binder. Examples of amorphous silica precursors that are preferably used herein include silicon compounds represented by the general formula SiX₄ (wherein X is a halogen, or methoxyl, ethoxyl or acetyl group), silanols that are hydrolysates of the above silicon compounds, and polysiloxanes having mean molecular weights of 3000 or less. Specific examples of such amorphous silica precursors include tetraethoxysilane, tetraisopropoxysilane, tetra-n-propoxysilane, tetrabutoxysilane and tetramethoxysilane. These compounds can be used either singly or in combination.

In the case where the photocatalytic treatment layer 33 is made up of a photocatalyst and a binder, the content of the photocatalyst in the photocatalytic treatment layer 33 is from 5 to 60% by weight, preferably from 20 to 50% by weight.

Besides the photocatalyst and the binder, such surface-active agents as those described in e.g., Japanese Laid-Open Patent Publication No. 2000-249821, and other additives may be incorporated in the photocatalytic treatment layer 33.

It is preferred that the thickness of the photocatalytic treatment layer 33 be in the range of 0.05 to 10 μm.

Examples of processes that can be used to form the photocatalytic treatment layer 3 using only a photocatalyst include vacuum processes such as chemical vapor deposition, sputtering, and vacuum deposition. A vacuum process ensures formation of a uniform photocatalyst film that serves as the photocatalytic treatment layer 33. The uniform photocatalytic treatment layer 33 makes it possible to treat the luminescent layer 3 uniformly. Further, the photocatalytic treatment layer 33, a film of a catalyst only, acts on the luminescent layer 3 more efficiently than a photocatalytic treatment layer 33 made up of a photocatalyst and a binder.

Examples of methods that can be used to form a photocatalytic treatment layer 33 using only a photocatalyst include the following: if titanium dioxide is used as the photocatalyst, a film of amorphous titania is first formed on a base 32 and then sintered so that the amorphous titania undergoes change in phase to become crystalline one.

Amorphous titania can be obtained by subjecting an inorganic salt of titanium, such as titanium tetrachloride or titanium sulfate, to hydrolysis and dehydration-condensation, or by subjecting an organic titanium compound, such as tetraethoxytitanium, tetraisopropoxytitanium, tetra-n-propoxytitanium, tetrabutoxytitanium, or tetramethoxytitanium to hydrolysis and dehydration-condensation in the presence of an acid. Amorphous titania can be modified into anatase by sintering it at a temperature between 400° C. and 500° C., and into rutile by sintering it at a temperature between 600° C. and 700° C.

Examples of methods that can be used to form a photocatalytic treatment layer 33 using a photocatalyst and a binder include the following: in the case where organopolysiloxane is used as the binder, a photocatalytic-treatment-layer-forming coating liquid is prepared by dispersing, in a solvent, a photocatalyst and organopolysiloxane, binder, and, if necessary, other additives, and the coating liquid prepared is applied to a base 32. If the photocatalytic-treatment-layer-forming coating liquid contains an ultraviolet-curing component as the binder, curing treatment applying ultraviolet light may be carried out after application of the coating liquid.

The solvent for use in the above method is preferably an alcoholic organic solvent such as ethanol or isopropanol. A conventional process such as spin, spray, dip, roll or bead coating can be used to apply the photocatalytic-treatment-layer-forming coating liquid to the base 32.

Another method that can be used to form a photocatalytic treatment layer 33 using a photocatalyst and a binder is as follows. In the case where an amorphous silica precursor is used as the binder, a photocatalytic-treatment-layer-forming coating liquid is prepared by uniformly dispersing, in a non-aqueous solvent, photocatalyst particles and the amorphous silica precursor, and the coating liquid prepared is applied to a base 32. The amorphous silica precursor is hydrolyzed with water in the air to form silanol, and the silanol is subjected to dehydration and condensation polymerization at normal temperatures. If the dehydration and condensation polymerization of the silanol is conducted at a temperature of 100° C. or more, the silanol is polymerized to a higher degree, so that the photocatalytic treatment layer 33 formed has increased surface strength.

The photocatalytic treatment layer 33 may be formed on the entire surface of the base 32. Alternatively, the photocatalytic treatment layer 33 may be formed pattern-wise on the base 32.

If the photocatalytic treatment layer 33 has been formed pattern-wise, it is possible to treat pattern-wise the substrate 1 having thereon the luminescent layer 3 to remove organic ligands, by applying energy after placing the photocatalytic treatment layer 33 above the luminescent layer 3, leaving a specified gap. For example, if the luminescent layer 3 has been formed pattern-wise, the patterned photocatalytic treatment layer 33 makes it possible to treat only the areas of the patterned luminescent layer 3 with energy, while keeping the other areas of the luminescent layer 3 untreated.

Any process can be used to pattern the photocatalytic treatment layer 33, and a photolithographic process can be used, for example.

### (Base 32)

The transparency of the base 32 to be used for the photocatalytic treatment plate 31 is selected according to the direction in which energy is applied, which will be described later, and to the direction from which light is extracted from the EL device finally obtained.

For example, when the EL device shown in FIG. 6(c) is of top emission type, and the substrate 1 or the first electrode layer 2 in the EL device is opaque, it is inevitable to apply energy from the photocatalytic treatment plate 31 side. The base 32 therefore has to be transparent in this case. On the other hand, when the EL device shown in FIG. 6(c) is of bottom emission type, energy can be applied from the substrate 1 side, so that the base 32 need not be transparent.

Further, the base 32 may be either flexible one such as a resin film, or non-flexible one such as a glass plate.

Any material can be used for the base 32. However, since the photocatalytic treatment plate 31 is repeatedly used, a material that has specified strength and whose surface is excellent in adhesion to the photocatalytic treatment layer 33 is favorably used. Specific examples of materials useful for the base 32 include glass, ceramics, metals, and plastics.

An anchor layer may be formed on the base 32 for the purpose of improving the adhesion between the base 32 surface and the photocatalytic treatment layer 33. Examples of materials that can be used to form the anchor layer include silane coupling agents and titanium coupling agents.

### (Light-Shielding Film)

The photocatalytic treatment plate 31 for use in this embodiment may comprise a patterned light-shielding film. A photocatalytic treatment plate 31 comprising a patterned light-shielding film makes it possible to treat, for removing organic ligands, pattern-wise the substrate 1 having thereon the luminescent layer 3. For example, when the luminescent layer 3 has been formed pattern-wise, the photocatalytic treatment plate 31 comprising a patterned light-shielding film makes it possible to treat only the areas of the patterned luminescent layer 3 with energy. It is therefore possible not to apply energy to the other areas of the patterned luminescent layer 3.

The light-shielding film is formed in the following order: the light-shielding film is formed pattern-wise on the base 32, and the photocatalytic treatment layer 33 is formed on the light-shielding film; or the photocatalytic treatment layer 33 is formed on the base 32, and the light-shielding film is formed pattern-wise on the photocatalytic treatment layer 33; or the photocatalytic treatment layer 33 is formed on one surface of the base 32, and the light-shielding film is formed pattern-wise on the other surface of the base 32.

When the light-shielding film has been formed on the base 32 or on the photocatalytic treatment layer 33, it is to be situated around the area in which the photocatalytic treatment layer 33 is placed above the luminescent layer 3, leaving a specified gap, so that the influences of scattering of energy within the base 32 can be lessened. Therefore, in this case, energy can be applied pattern-wise with extremely high accuracy.

Further, in the case where the light-shielding film has been formed on the photocatalytic treatment layer 33, when the photocatalytic treatment layer 33 is placed above the luminescent layer 3, leaving a specified gap, the light-shielding film can serve as a spacer if it has a thickness equal to the gap. Namely, when the photocatalytic treatment layer 33 is placed above the luminescent layer 3, leaving a specified gap, it is possible to hold the gap between the luminescent layer 3 and the photocatalytic treatment layer 33 if the light-shielding film is brought into contact with the luminescent layer 3.

Any process can be used to form the light-shielding film, and a suitable process is selected according to the characteristics of the surface on which the light-shielding film is formed and to the required energy-shielding properties.

For example, the light-shielding film can be formed by depositing, by such a process as sputtering or vacuum vapor deposition, a thin film of a metal such as chromium, having a thickness in the order of 1000 to 2000 angstroms, and patterning this thin film. A conventional process can be employed to pattern the thin metal film.

Alternatively, the light-shielding film can also be formed by patterning a layer containing light-shielding particles, such as carbon fine particles, a metallic oxide, an inorganic pigment or an organic pigment, that are dispersed in a resin binder. Examples of the resin binder useful herein include polyimide resins, acrylic resins, epoxy resins, polyacrylamide, polyvinyl alcohol, gelatin, casein and cellulose. These resins can be used either singly or in combination. Moreover, photosensitive resins, O/W-emulsion-type resin compositions such as emulsified reactive silicones, and the like can also be used for the resin binder. A conventional process such as a photolithographic process or a printing process can be used for patterning in this method.

The thickness of the light-shielding film using a resin binder can be set to 0.5 to 10 μm.

### (Primer Layer)

In this embodiment, if the patterned light-shielding film is formed on the base 32, and the photocatalytic treatment layer 33 is formed on the light-shielding film, it is preferable to form a primer layer on the light-shielding film before forming the photocatalytic treatment layer 33.

The action and function of this primer layer are not yet clear. The primer layer, however, is considered to have the function of preventing diffusion of impurities from the film portions of and the openings in the patterned light-shielding film, especially residues remaining after patterning the light-shielding film, as well as impurities such as metals and metal ions, which retard the photocatalytic action in removing the organic ligands 21 from the luminescent layer 3. Therefore, the primer layer formed between the light-shielding film and the photocatalytic treatment layer 33 can make the treatment for removal of organic ligands from the luminescent layer 3 progress with high sensitivity.

The primer layer is considered to prevent the impurities present not only in the film portions of but also in the openings in the patterned light-shielding film, from affecting the photocatalytic action. It is therefore preferred that the primer layer be formed entirely on the patterned light-shielding film so that it covers both the film portions and the openings. Further, the primer layer can fulfill its purpose as long as it is so situated that the photocatalytic treatment layer 33 and the light-shielding film do not come into physical contact with each other.

Although any material can be used to form the primer layer, an inorganic material that is not easily decomposed photocatalytically is preferred. For example, amorphous silica can be mentioned as the inorganic material. Useful herein as precursors of amorphous silica are silicon compounds represented by the general formula SiX₄ (where X represents a halogen, methoxyl group, ethoxyl group, or acetyl group), silanols that are hydrolysates of the above silicon compounds, and polysiloxanes having mean molecular weights of 3000 or less.

It is preferred that the thickness of the primer layer be in the range of 0.001 to 1 μm, particularly in the range of 0.001 to 0.5 μm.

(ii) Placement of Photocatalytic Treatment Plate 31 above Luminescent Layer 3

In this embodiment, the photocatalytic treatment plate 31 is placed above the luminescent layer 3, leaving such a gap that the photocatalytic action accompanied by the application of energy can reach the luminescent layer 3. Generally, the photocatalytic treatment plate 31 is placed above the luminescent layer 3 so that the photocatalytic treatment layer 33 and the luminescent layer 3 makes such a gap that the photocatalytic action accompanied by the application of energy can reach the luminescent layer 3.

The gap herein encompasses no gap that is made when the photocatalytic treatment layer 33 is brought into contact with the luminescent layer 3.

Specifically, it is preferred that the gap between the photocatalytic treatment layer 33 and the luminescent layer 3 be 200 μm or less. When the photocatalytic treatment layer 33 is placed above the luminescent layer 3, leaving such a gap, active oxygen species generated from oxygen and water by the photocatalytic action can easily be attached or detached. When the gap between the photocatalytic treatment layer 33 and the luminescent layer 3 is greater than 200 μm, the active oxygen species generated by the photocatalytic action may not be able to reach the luminescent layer 3 easily, slowing down the treatment rate. On the other hand, when the gap between the photocatalytic treatment layer 33 and the luminescent layer 3 is excessively small, the active oxygen species generated from oxygen and water by the photocatalytic action may not be able to be attached or detached easily, slowing down the treatment rate.

If that the photocatalyst is highly sensitive and that the efficiency in removing organic ligands 21 is high are taken into account, it is more preferred that the gap between the photocatalytic treatment layer 33 and the luminescent layer 3 be from 0.2 to 20 μm, more preferably from 1 to 10 μm.

On the other hand, in the production of an EL device having a large area of e.g., 300 mm×300 mm, it is extremely difficult to make a very small gap as described above between the photocatalytic treatment plate 31 and the luminescent layer 3. Therefore, the gap between the photocatalytic treatment plate 31 and the luminescent layer 3 is preferably from 5 to 100μ, more preferably from 10 to 75 μm, in the production of an EL device having a relatively large area. This is because as long as the gap is in the above range, lowering of the sensitivity of the photocatalyst is not brought about, so that efficiency in removing organic ligands 21 is not impaired.

Further, when energy is applied to a relatively large area, it is preferred that, on a device for positioning the photocatalytic treatment plate 31 and the luminescent layer 3, contained in energy irradiation equipment, the gap be set to a value in the range of 10 to 200 μm, particularly in the range of 25 to 75 μm. This is because when the gap has been set to a value in the above range, the photocatalytic treatment plate 31 can be placed above the luminescent layer 3 without bringing the former into contact with the latter, and without bringing about a significant decrease in the sensitivity of the photocatalyst.

In this embodiment, it is enough to maintain this gap only while energy is applied.

For example, a spacer can be used to place the photocatalytic treatment layer 33 above the luminescent layer 3, leaving uniformly an extremely small gap as described above. If a spacer is used, there can be made a uniform gap. Moreover, the photocatalyst does not act on those portions of the luminescent layer 3 that are in contact with the spacer. It is therefore possible to treat pattern-wise the luminescent layer 3 for removal of organic ligands by the use of a spacer in the desired pattern.

In this embodiment, the spacer can be made separately as one member. However, when simplification of the process, etc. are taken into consideration, it is preferable to form the spacer on the photocatalytic treatment layer 33 in the photocatalytic treatment plate 31. Such a spacer has the same advantages as those mentioned in the description of the light-shielding film.

As long as the spacer has at least the property of shielding the luminescent layer 3 surface from the photocatalytic action, its purpose is fulfilled. Therefore, the spacer need not have the property of shielding energy to be applied.

(iii) Application of Energy

In this embodiment, the organic ligands 21 are removed from the luminescent layer 3 by applying energy from a specified direction after placing the photocatalytic treatment layer 33 above the luminescent layer 3, leaving a specified gap.

Light having a wavelength of usually 450 nm or less, preferably 380 nm or less, is applied. This is because titanium dioxide is a photocatalyst favorably used for the photocatalytic treatment layer 33, and energy that activates the photocatalytic action of titanium dioxide is preferably light having a wavelength in the above range.

Examples of light sources that can be used for the application of energy include mercury lamps, metal halide lamps, xenon lamps, and excimer lamps.

Energy may be applied pattern-wise. Pattern-wise application of energy makes it possible to carry out pattern-wise the treatment for removing organic ligands. For applying energy pattern-wise, there can be used a method in which energy from any of the above light sources is applied through a patterned photomask, as well as a method in which energy is applied pattern-wise using a laser such as an excimer laser or YAG.

Energy is applied in an amount needed to remove the organic ligands 21 from the luminescent layer 3 by the action of the photocatalyst contained in the photocatalytic treatment layer 33.

Preferably, energy is applied while heating the photocatalytic treatment layer 33. This is because, by doing so, the sensitivity of the photocatalyst can be increased, and the organic ligands 21 can thus be removed efficiently. Specifically, it is preferable to heat the photocatalytic treatment layer 33 at a temperature between 30° C. and 80° C.

If a silane coupling agent is used as the organic ligand 21, the photocatalytic treatment layer 33 is not heated so as not to raise the reactivity of the silane coupling agent.

The direction in which energy is applied is determined by the degree of transparency of the base 32, the direction in which light is extracted from the EL device finally obtained, and so forth.

For example, when the light-shielding film is present in the photocatalytic treatment plate 31, and the base 32 in the photocatalytic treatment plate 31 is transparent, energy is applied from above the photocatalytic treatment plate 31. If the light-shielding film exists on the photocatalytic treatment layer 33 and serves as a spacer, energy may be applied either from the photocatalytic treatment plate 31 side or from the substrate 1 side.

Further, for example, when the photocatalytic treatment layer 33 has been formed pattern-wise, energy may be applied from any direction as long as it reaches the facing areas of the photocatalytic treatment layer 33 and the luminescent layer 3, as mentioned above.

Also in the case where the above-described spacer is used, energy may be applied from any direction as long as it reaches the facing areas of the photocatalytic treatment layer 33 and the luminescent layer 3.

Furthermore, for example, when a photomask is used, energy is applied through the photomask. In this case, the component layers to be situated under the photomask must be transparent.

After the application of energy, the photocatalytic treatment plate 31 is removed from the luminescent layer 3.

That the organic material has been removed can be confirmed by Fourier transform infrared spectroscopic analysis (FT-IR), time-of-flight secondary ion mass spectrometric analysis (TOF-SIM), or the like.

### 2. Other Steps

Also in this embodiment, the step of forming, on the first electrode layer 2, a hole injection transporting layer 5 having the property of injecting holes may be performed between the first-electrode-layer-forming step and the luminescent-layer-forming step, as illustrated in FIGS. 7(a) to 7(d) (see FIGS. 7(a) and 7(b)), like in the first embodiment. The hole injection transporting layer 5 stabilizes the injection of holes into the luminescent layer 3 and makes the transportation of holes smooth, which leads to enhancement of emission efficiency. The hole injection transporting layer 5 in this embodiment is the same as the hole injection transporting layer 5 in the first embodiment.

Further, the step of forming an electron injection transporting layer, the step of forming an insulating layer, and so on may also be performed in this embodiment, as in the first embodiment.

The present invention may be embodied in other specific forms without departing from the spirit or essential characteristics thereof. The above embodiments are therefore to be considered in all respects as illustrative and not restrictive. The scope of the invention is indicated by the appended claims rather than by the foregoing description and all changes that come within the meaning and range of equivalency of the claims are embraced therein.

### EXAMPLES

The present invention will now be explained more specifically by way of the following Examples and Comparative Examples.

### Example 1

A suspension of quantum dots 22 (CdSe/ZnS core-shell-type nanoparticles, diameter: 5.2 nm) protected by TOPO (fluorescent semiconductor nanocrystal “Evidot” manufactured by evident TECHNOLOGIES) was first prepared. A glass substrate 1 having thereon a patterned ITO electrode 2 was spin-coated with the suspension of the quantum dots 22 protected by TOPO, thereby forming a luminescent layer 3 with a thickness of about 20 nm. Subsequently, the luminescent layer 3 was treated for 15 minutes in an ultraviolet-ozone cleaner. After this treatment, it was confirmed by FT-IR analysis that the organic material had been removed from the luminescent layer 3.

After this, LiF was vacuum-deposited to a thickness of 1 nm, and Al, to a thickness of 100 nm. In this manner, an EL device was obtained.

The EL device began to emit light at about 3 V and was confirmed to emit red light originating in the quantum dots 22.

### Comparative Example 1

An EL device was produced in the same manner as in Example 1, except that the luminescent layer 3 was not treated in the UV-ozone cleaner.

### [Evaluation of EL Devices of Example 1 and Comparative Example 1]

The life of the EL device of Example 1 and that of the EL device of Comparative Example 1 were checked under a constant electric current. The EL device of Comparative Example 1 emitted light for about 10 hours, while that of Example 1 continued to emit light for about 20 hours. It was thus confirmed that the duration of emission was prolonged from about 10 hours to about 20 hours by conducting the UV-ozone cleaning.

### Example 2

A suspension of quantum dots 22 (CdSe/ZnS core-shell-type nanoparticles, diameter: 5.2 nm) protected by TOPO (fluorescent semiconductor nanocrystal “Evidot” manufactured by evident TECHNOLOGIES) was first prepared. A glass substrate 1 having thereon a patterned ITO electrode 2 was spin-coated with the suspension of the quantum dots 22 protected by TOPO, thereby forming a luminescent layer 3 with a thickness of about 20 nm. Subsequently, the luminescent layer 3 was subjected to plasma treatment for 5 minutes at 200 W and at an O₂ gas flow rate of 60 sccm. After this treatment, it was confirmed by FT-IR analysis that the organic material had been removed from the luminescent layer 3.

After this, LiF was vacuum-deposited to a thickness of 1 nm, and Al, to a thickness of 100 nm. In this manner, an EL device was obtained.

The EL device began to emit light at about 3 V and was confirmed to emit red light originating in the quantum dots 22.

### Comparative Example 2

An EL device was produced in the same manner as in Example 2, except that the luminescent layer 3 was not subjected to the plasma treatment.

### [Evaluation of EL Devices of Example 2 and Comparative Example 2]

The life of the EL device of Example 2 and that of the EL device of Comparative Example 2 were checked under a constant electric current. The EL device of Comparative Example 2 emitted light for about 10 hours, while that of Example 2 continued to emit light for about 15 hours. It was thus confirmed that the duration of emission was prolonged from about 10 hours to about 15 hours by carrying out the plasma treatment.

### Example 3

### (Formation of Luminescent Layer 3)

A suspension of quantum dots 22 (CdSe/ZnS core-shell-type nanoparticles, diameter: 5.2 nm) protected by TOPO (fluorescent semiconductor nanocrystal “Evidot” manufactured by evident TECHNOLOGIES) was first prepared. A glass substrate 1 having thereon a patterned ITO electrode 2 was spin-coated with the suspension of the quantum dots 22 protected by TOPO, thereby forming a luminescent layer 3 with a thickness of about 20 nm.

### (Preparation of Photocatalytic Treatment Plate 31)

Next, a photomask so designed that it was useful for forming a patterned light-shielding film having openings, each opening being in the shape of a rectangle of 85 μm×85 μm, was prepared, the pattern of the light-shielding film being the same as that of the ITO electrode 2. A photocatalytic-treatment-layer-forming coating liquid having the following composition was applied to the photomask with a spin coater and was heated and dried at 150° C. for 10 minutes to cause hydrolysis and condensation polymerization reaction, thereby curing the coating. In this manner, there was formed a transparent photocatalytic treatment layer 33 with a thickness of 2000 angstroms, in which the photocatalyst was firmly fixed in the organosiloxane.

### <Composition of Photocatalytic-Treatment-Layer-Forming Coating Liquid>

Titanium dioxide (ST-K01 manufactured by Ishihara Sangyo Kaisha, Ltd., Japan) 2 parts by weight Organoalkoxysilane (TSL8113 manufactured by GE Toshiba Silicone Co., Ltd., Japan) 0.4 parts by weight Isopropyl alcohol 3 parts by weight

### (Removal of Organic Ligands 21)

Next, with UV irradiation equipment having a high-pressure mercury vapor lamp as a light source, and a mechanism for positioning the photocatalytic treatment plate 31 and the substrate 1 having thereon the luminescent layer 3, light of 253 nm was applied in an amount of 200 mJ/cm² to the back surface of the photocatalytic treatment plate 31, after positioning the photocatalytic treatment plate 31 and the substrate 1 so that the openings in the patterned light-shielding film contained in the photocatalytic treatment plate 31 agreed with the film portions of the patterned ITO electrode 2 formed on the substrate 1 having thereon the luminescent layer 3, and that the distance between the two was 20 μm.

After this treatment, it was confirmed by FT-IR analysis that the organic material had been removed from the luminescent layer 3.

### (Formation of Electrode)

After this, LiF was vacuum-deposited to a thickness of 1 nm, and Al, to a thickness of 100 nm. In this manner, an EL device was obtained.

### (Evaluation)

The EL device began to emit light at about 3 V and was confirmed to emit red light originating in the quantum dots 22.

### Comparative Example 3

An EL device was produced in the same manner as in Example 3, except that the luminescent layer 3 was not subjected to the treatment using the photocatalytic treatment plate 31.

### [Evaluation of EL Devices of Example 3 and Comparative Example 3]

The life of the EL device of Example 3 and that of the EL device of Comparative Example 3 were checked under a constant electric current. The EL device of Comparative Example 3 emitted light for about 10 hours, while that of Example 3 continued to emit light for about 25 hours. It was thus confirmed that the duration of emission was prolonged from about 10 hours to about 25 hours by carrying out the treatment using the photocatalytic treatment plate 31.

### Example 4

On a glass substrate having thereon a patterned ITO electrode 2, MoO₃ was deposited to a thickness of 10 nm to form a hole injection layer (hole injection transporting layer 5). Subsequently, a luminescent layer 3 was formed and treated in an ultraviolet-ozone cleaner in the same manner as in Example 1. After this treatment, it was confirmed by FT-IR analysis that the organic material had been removed from the luminescent layer 3.

Next, BAlq₂ film with a thickness of 20 nm and Alq₃ film with a thickness of 20 nm were formed to form an electron transporting layer. Subsequently, LiF was deposited to a thickness of 1 nm, and Al, to a thickness of 100 nm, thereby making an electrode.

The EL device obtained in the above-described manner began to emit light at about 3 V and was confirmed to emit red light originating in the quantum dots 22.

### Comparative Example 4

An EL device was produced in the same manner as in Example 4, except that the luminescent layer 3 was not treated in the UV-ozone cleaner.

### [Evaluation of EL Devices of Example 4 and Comparative Example 4]

The life of the EL device of Example 4 and that of the EL device of Comparative Example 4 were checked under a constant electric current. The EL device of Comparative Example 4 emitted light for about 20 hours, while that of Example 4 continued to emit light for about 100 hours. It was thus confirmed that the duration of emission was prolonged from about 20 hours to about 100 hours by carrying out the UV-ozone cleaning.

### Example 5

An EL device was produced in the same manner as in Example 4, except that the same plasma treatment as in Example 2 was carried out instead of the UV-ozone cleaning conducted in Example 4. After the plasma treatment, it was confirmed by FT-IR analysis that the organic material had been removed from the luminescent layer 3.

The EL device obtained began to emit light at about 3 V and was confirmed to emit red light originating in the quantum dots 22.

### Comparative Example 5

An EL device was produced in the same manner as in Example 5, except that the luminescent layer 3 was not subjected to the plasma treatment.

### [Evaluation of EL Devices of Example 5 and Comparative Example 5]

The life of the EL device of Example 5 and that of the EL device of Comparative Example 5 were checked under a constant electric current. The EL device of Comparative Example 5 emitted light for about 15 hours, while that of Example 5 continued to emit light for about 90 hours. It was thus confirmed that the duration of emission was prolonged from about 15 hours to about 90 hours by carrying out the oxygen plasma treatment.

### Example 6

An EL device was produced in the same manner as in Example 4, except that the organic ligands were removed not by carrying out the UV-ozone cleaning but in the same manner as in Example 3. After carrying out the treatment for removing the organic ligands, it was confirmed by FT-IR analysis that the organic material had been removed from the luminescent layer 3.

The EL device began to emit light at about 3 V and was confirmed to emit red light originating in the quantum dots 22.

### Comparative Example 6

An EL device was produced in the same manner as in Example 6, except that the luminescent layer 3 was not subjected to the treatment using the photocatalytic treatment plate 31.

### [Evaluation of EL Devices of Example 6 and Comparative Example 6]

The life of the EL device of Example 6 and that of the EL device of Comparative Example 6 were checked under a constant electric current. The EL device of Comparative Example 6 emitted light for about 25 hours, while that of Example 6 continued to emit light for about 120 hours. It was thus confirmed that the duration of emission was prolonged from about 25 hours to about 120 hours by carrying out the treatment using the photocatalytic treatment plate 31.

1. A process for producing an electroluminescent device, comprising the steps of:
preparing a substrate,
forming a first electrode layer on the substrate,
forming a luminescent layer on the first electrode layer by applying, to the first electrode layer, a luminescent-layer-forming coating liquid containing quantum dots, each quantum dot being surrounded by organic ligands,
removing the organic ligands from the quantum dots by subjecting the luminescent layer to UV-ozone cleaning, and
forming a second electrode layer on the luminescent layer in which the organic ligands have been removed from the quantum dots.

2. The process for producing an electroluminescent device according to claim 1, further comprising, between the first-electrode-layer-forming step and the luminescent-layer-forming step, the step of forming, on the first electrode layer, a hole injection transporting layer of an inorganic material having the property of injecting holes.

3. The process for producing an electroluminescent device according to claim 1, wherein the quantum dot is composed of a core part made of a semiconductor fine particle and a shell part covering the core part, made from a material having a greater band gap than the semiconductor fine particle.

4. A process for producing an electroluminescent device, comprising the steps of:
preparing a substrate,
forming a first electrode layer on the substrate,
forming a luminescent layer on the first electrode layer by applying, to the first electrode layer, a luminescent-layer-forming coating liquid containing quantum dots, each quantum dot being surrounded by organic ligands,
removing the organic ligands from the quantum dots by plasma irradiation of the luminescent layer, and
forming a second electrode layer on the luminescent layer in which the organic ligands have been removed from the quantum dots.

5. The process for producing an electroluminescent device according to claim 4, further comprising, between the first-electrode-layer-forming step and the luminescent-layer-forming step, the step of forming, on the first electrode layer, a hole injection transporting layer of an inorganic material having the property of injecting holes.

6. The process for producing an electroluminescent device according to claim 4, wherein the quantum dot is composed of a core part made of a semiconductor fine particle and a shell part covering the core part, made from a material having a greater band gap than the semiconductor fine particle.

7. A process for producing an electroluminescent device, comprising the steps of:
preparing a substrate,
forming a first electrode layer on the substrate,
forming a luminescent layer on the first electrode layer by applying, to the first electrode layer, a luminescent-layer-forming coating liquid containing quantum dots, each quantum dot being surrounded by organic ligands,
placing, above the luminescent layer, a photocatalytic treatment layer containing at least a photocatalyst,
removing the organic ligands from the quantum dots by applying energy to the photocatalytic treatment layer, and
forming a second electrode layer on the luminescent layer in which the organic ligands have been removed from the quantum dots.

8. The process for producing an electroluminescent device according to claim 7, further comprising, between the first-electrode-layer-forming step and the luminescent-layer-forming step, the step of forming, on the first electrode layer, a hole injection transporting layer of an inorganic material having the property of injecting holes.

9. The process for producing an electroluminescent device according to claim 7, wherein the quantum dot is composed of a core part made of a semiconductor fine particle and a shell part covering the core part, made from a material having a greater band gap than the semiconductor fine particle.
